(19) United States
(12) Patent Application Publication
(10) Pub. No.: US 2008/0092947 A1
(43) Pub. Date: Apr. 24, 2008

(54) PULSE PLATING OF A LOW STRESS FILM ON A SOLAR CELL SUBSTRATE

(75) Inventors: Sergey Lopatin, Morgan Hill, CA (US); Charles Gay, Westlake Village, CA (US); David Eaglesham, Livermore, CA (US); John O. Dukovic, Palo Alto, CA (US); Nicolay Y. Kovarsky, Sunnyvale, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/552,497

(22) Filed: Oct. 24, 2006

(51) Int. Cl. H01L 31/00

(52) U.S. Cl. 136/255

(57) ABSTRACT

Embodiments of the invention contemplate the formation of a low cost solar cell metal contact structure that has improved electrical and mechanical properties through the use of an electrochemical plating process. The resistance of interconnects formed in a solar cell device greatly affects the efficiency of the solar cell. It is thus desirable to form a solar cell device that has a low resistance connections that is reliable and cost effective. One or more embodiments of the invention described herein are adapted to form a low cost and reliable interconnecting layer using an electrochemical plating process containing common metal, such as copper. However, generally the electroplated portions of the interconnecting layer may contain a substantially pure metal or a metal alloy layer. Methods are discussed herein that are used to form a solar cell containing conductive metal interconnect layer(s) that have a low intrinsic stress.

### BACKGROUND OF THE INVENTION

1. Field of the Invention

Embodiments of the present invention generally relate to the fabrication of photovoltaic cells and particularly to the formation of layers on a substrate by use of an electrochemical deposition process.

2. Description of the Related Art

Solar cells are photovoltaic devices that convert sunlight directly into electrical power. The most common solar cell material is silicon, which is in the form of single or polycrystalline wafers. Because the cost of forming a silicon-based solar cells is higher than the cost of generating electricity using traditional methods, there has been an effort to reduce the cost to form solar cells.

FIGS. 1A and 1B schematically depicts a standard silicon wafer 100 fabricated on a wafer 110. The wafer 110 includes a p-type base region 101, an n-type emitter region 102, and a p-n junction region 103 disposed therebetween. An n-type region, or n-type semiconductor, is formed by doping the semiconductor with certain types of elements (e.g., phosphorus (P), arsenic (As), or antimony (Sb)) in order to increase the number of negative charge carriers, i.e., electrons. Similarly, a p-type region, or p-type semiconductor, is formed by the addition of trivalent atoms to the crystal lattice, resulting in a missing electron from one of the four covalent bonds normal for the silicon lattice. Thus the dopant atom can accept an electron from a neighboring atoms' covalent bond to complete the fourth bond. The dopant atom accepts an electron, causing the loss of half of one bond from the neighboring atom and resulting in the formation of a “hole”.

When light falls on the solar cell, energy from the incident photons generates electron-hole pairs on both sides of the p-n junction region 103. Electrons diffuse across the p-n junction to a lower energy level and holes diffuse in the opposite direction, creating a negative charge on the emitter and a corresponding positive charge builds up in the base. When an electrical circuit is made between the emitter and the base and the p-n junction is exposed to certain wavelengths of light, a current will flow. The electrical current generated by the semiconductor when illuminated flows through contacts disposed on the frontside 120, i.e. the light-receiving side, and the backside 121 of the solar cell 100. The top contact structure is generally configured as widely-spaced thin metal strips, or fingers 104, that supply current to a larger bus bar 105. The back contact 106 is generally not constrained to be formed in multiple thin strips, since it does not prevent incident light from striking solar cell 100. Solar cell 100 is generally covered with a thin layer of dielectric material, such as Si₃N₄, to act as an anti-reflection coating 111, or ARC, to minimize light reflection from the top surface of solar cell 100.

In the interest of simplified assembly and higher efficiency of solar cells, a solar cell has been developed, wherein a plurality of holes is formed through the solar cell substrate and serves as vias for interconnection of the top contact structure to a backside conductor by using pins. This solar cell design is referred to as a pin-up module, or PUM. One advantage of the PUM concept is the elimination of the busbars, such as bus bar 105 illustrated in FIG. 1A, from covering the light-receiving side of the substrate, thereby increasing efficiency of the cell. Another is that resistive losses are reduced because current produced by the solar cell is collected at holes equally spaced over the substrate rather than requiring some of the connections to extend across the surface of the solar cell. Further, resistive losses experienced by a PUM connected device will not increase as the solar cell surface area increases and, hence, larger solar cells may be manufactured without a loss in efficiency.

FIG. 1C is a partial schematic cross section of one example of a PUM cell 130 showing a contact 134. Similar to a standard solar cell, such as solar cell 100, PUM cell 130 includes a single crystal silicon wafer 110 with a p-type base region 101, an n-type emitter region 102, and a p-n junction region 103 disposed therebetween. PUM cell 130 also includes a plurality of through-holes 131, which are formed between the light-receiving surface 132 and the backside 133 of PUM cell 130. The through-holes 131 allow the formation of contact 134 between the light-receiving surface 132 and the backside 133. Disposed in each through-hole 131 is a contact 134, which includes a top contact structure 135 disposed on light-receiving surface 132, a backside contact 136 disposed on backside 133, and an interconnect 137, which fills through-hole 131 and electrically couples top contact structure 135 and backside contact 136. An anti-reflective coating 107 may also be formed on light-receiving surface 132 to minimize reflection of light energy therefrom.

The surfaces of contact 134 that are in contact with wafer 110 are adapted to form an ohmic connection with n-type emitter region 102. An ohmic contact is a region on a semiconductor device that has been prepared so that the current-voltage (I-V) curve of the device is linear and symmetric, i.e., there is no high resistance interface between the doped silicon region of the semiconductor device and the metal contact. Low-resistance, stable contacts are critical for the performance of the solar cell and reliability of the circuits formed in the solar cell fabrication process. Hence, after contact 134 has been formed in through-hole 131, on light-receiving surface 132, and on backside 133, an annealing process of suitable temperature and duration is typically performed in order to produce the necessary low resistance metal silicide at the contact/semiconductor interface. A backside contact 139 completes the electrical circuit required for PUM cell 130 to produce a current by forming an ohmic contact with p-type base region 101 of wafer 110.

Top contact structure 135 is configured to act as one or more of the fingers of a conventional solar cell, such as fingers 104 of solar cell 100 depicted in FIGS. 1A-1B. Wider conductors on light-receiving surface 132 reduce resistance losses, but increase shadowing losses by covering more of light-receiving surface 132. Therefore, maximizing cell efficiency requires balancing these opposing design constraints. FIG. 1D illustrates a plan view of one example of a top contact structure 135 for a PUM cell, wherein the finger width and geometry have been optimized to maximize cell efficiency for the cell. In this configuration, a top contact structure 135 for a PUM cell is configured as a grid electrode 138, which consists of a plurality of various width finger segments 135A. The width of a particular finger segment 135A is selected as a function of the current to be carried by that finger segment 135A. In addition, finger segments 135A are configured to branch as necessary to maintain finger spacing as a function of finger width. This minimizes resistance losses as well as shadowing by finger segments 135A.

Grid electrode contacts for PUM cells have been fabricated using a screen printing process in which a silver-containing paste is deposited in a desired pattern on a substrate surface and pressed into the through-holes 131 in the substrate surface, and then annealed. However, there are several issues with this manufacturing method. First, the thin fingers of the grid electrode, when formed by the screen printing process, may be discontinuous since the fingers formed using a metal paste containing do not always agglomerate into a continuous interconnecting line during the annealing process. Second, porosity present in the grid electrode formed during the agglomeration process results in greater resistive losses. Third, electrical shunts may be formed by diffusion of silver from the contact into the p-type base region or on the surface of the substrate backside. Shunts on the substrate backside are caused by poor definition of backside contacts such as waviness, and/or silver residue. Fourth, due to the relatively thin substrate thicknesses commonly used in solar cell applications, such as 200 micrometers and less, the act of screen printing the metal paste on the substrate surface can cause physical damage to the substrate. Lastly, silver-based paste is a relatively expensive material for forming conductive components of a solar cell.

One issue with the current method of forming metal interconnects using a screen printing process that utilizes a metal particle containing paste is that the process of forming the patterned features requires high temperature post-processing steps to densify the formed features and form a good electrical contact with the substrate surface. Due to the need to perform a high temperature sintering process the formed interconnect lines will have a high extrinsic stress created by the difference in thermal expansion of the substrate material and the metal lines. A high extrinsic stress, or even intrinsic stress, formed in the metal interconnect lines is an issue, since it can cause breakage of the formed metallized features, warping of the thin solar cell substrate, and/or delamination of the metallized features from the surface of the solar cell substrate. High temperature processes also limit the types of materials that can be used to form a solar cell due to the breakdown of certain materials at the high sintering temperatures. Also, screen printing processes also tend to be non-uniform, unreliable and often unrepeatable. Therefore, there is a need to form a low stress interconnect line that forms a strong bond to the surface of the substrate.

Another approach to forming very thin, robust fingers on the surface of a solar cell substrate involves cutting grooves in the surface of the substrate with a laser. The grooves are subsequently filled by an electroless plating method. However the laser-cut grooves are a source of macro- and micro-defects. The laser-cut edge is not well defined, causing waviness on the finger edges, and the heat of the laser introduces defects into the silicon.

Therefore, there is a need for a contact structure for solar cells having low resistivity and clearly defined features. Further, there is a need for a method of forming a contact structure for solar cells with low resistivity and clearly defined features that does not damage the solar cell substrate.

### SUMMARY OF THE INVENTION

Embodiments of the present invention generally provide a method for forming a metal interconnect in a solar cell substrate, comprising providing a substrate that has either an n-type region or a p-type region generally adjacent to a light-receiving surface of a substrate and a rear surface, forming a seed layer that contacts the n-type region or the p-type region on the light-receiving surface of the substrate and/or rear surface, and forming a first metal layer over the seed layer by immersing the seed layer and an electrode in a first electrolyte and biasing the seed layer relative to the electrode using one or more waveforms delivered from a power supply.

Embodiments of the present invention may further provide a method for forming a metal interconnect on a solar cell substrate, comprising providing an electrolyte container configured to receive and maintain a first electrolyte therein, the electrolyte container having an electrode disposed within the electrolyte container, providing a head assembly positioned above the electrolyte container, the head assembly including a substrate holder for supporting a substrate and a first electrode, wherein the substrate holder covers the processing surface of the substrate and the substrate holder has a plurality of features formed therein that preferentially allow regions of the processing surface to contact the first electrolyte, positioning a substrate in contact with the first electrolyte, the substrate holder and the first electrode, and applying one or more waveforms to the first electrode and a second electrode in an electroplating process.

Embodiments of the present invention may further provide a metal contact structure for a solar cell comprising an n-type region disposed on a substrate, a p-type region disposed on the substrate and adjacent to the n-type region, a first metal seed layer that is in electrical communication with the n-type region, wherein the first metal seed layer is deposited using a process selected from a group consisting of an electroless deposition process, a physical vapor deposition process, a chemical vapor deposition process and an atomic layer deposition process, a first metal layer that is formed over the first metal seed layer using an electrochemical deposition process using a first waveform, a second metal seed layer that is in electrical communication with the p-type region, wherein the second metal seed layer is deposited using a process selected from a group consisting of an electroless deposition process, a physical vapor deposition process, a chemical vapor deposition process and an atomic layer deposition process, and a second metal layer that is formed over the second metal seed layer using an electrochemical deposition process using a second waveform. The first metal layers and the second metal layers can be formed simultaneously on n-type and p-type regions in one process with using plurality of waveforms.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates an isometric view of prior art solar cell containing a front side metallization interconnect pattern.

FIG. 1B illustrates an cross-sectional side view of a prior art solar cell shown in FIG. 1A.

FIG. 1C illustrates a cross-sectional view of a prior art PUM type device.

FIG. 1D illustrates a plan view of a top contact structure of a PUM cell, wherein the finger width and geometry have been optimized to maximize cell efficiency.

FIG. 2A illustrates a solar cell process sequence according to one embodiment described herein.

FIG. 2B illustrates a solar cell process sequence according to one embodiment described herein.

FIGS. 3A-3F illustrate schematic cross-sectional views of a solar cell during different stages of the process sequence described in FIGS. 2A and 2B.

FIG. 4 illustrates a side cross-sectional view of an electrochemical processing chamber according to one embodiment described herein.

FIGS. 5A-5E illustrate various waveforms that can be used to electrochemically plated a metal layer on a surface of a substrate according to one embodiment described herein.

FIG. 5F illustrates schematic cross-sectional views of a metal layer formed using a the process sequence described herein.

FIG. 5G illustrates a waveforms that can be used to electrochemically plated a metal layer on a surface of a substrate according to one embodiment described herein.

For clarity, identical reference numerals have been used, where applicable, to designate identical elements that are common between figures. It is contemplated that features of one embodiment may be incorporated in other embodiments without further recitation.

### DETAILED DESCRIPTION

Embodiments of the invention contemplate the formation of a low cost solar cell metal contact structure that has improved electrical and mechanical properties by use of an electrochemical plating process. Solar cell substrates that may benefit from the invention include substrates composed of single crystal silicon, multi crystalline silicon, poly crystalline silicon, germanium (Ge), and gallium arsenide (GaAs), as well as heterojunction cells, such as GaInP/GaAs/Ge or ZnSe/GaAs/Ge substrates.

The resistance of interconnects formed in a solar cell device greatly affects the efficiency of the solar cell. It is thus desirable to form a solar cell device that has a low resistance connection that is reliable and cost effective. As noted above, silver (Ag) interconnecting lines formed from a silver paste is currently the preferred interconnecting method. However, while silver has a lower resistivity (e.g., 1.59×10⁻⁸ ohm-m) than other common metals such as copper (e.g., 1.7×10⁻⁸ ohm-m) and aluminum (e.g., 2.82×10⁻⁸ ohm-m) and it costs orders of magnitude more than these other common metals. Therefore, one or more embodiments of the invention described herein are adapted to form a low cost and reliable interconnecting layer using an electrochemical plating process containing common metal, such as copper. However, generally the electroplated portions of the interconnecting layer may contain a substantially pure metal or a metal alloy layer containing copper (Cu), silver (Ag), gold (Au), tin (Sn), cobalt (Co), rhenium (Rh), nickel (Ni), zinc (Zn), lead (Pb), palladium (Pd), and/or aluminum (Al). Preferably, the electroplated portion of the interconnect layer contains substantially pure copper or a copper alloy.

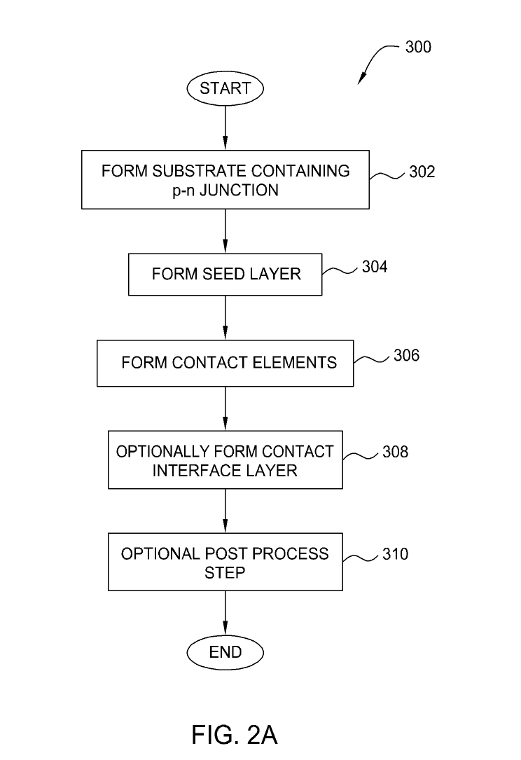

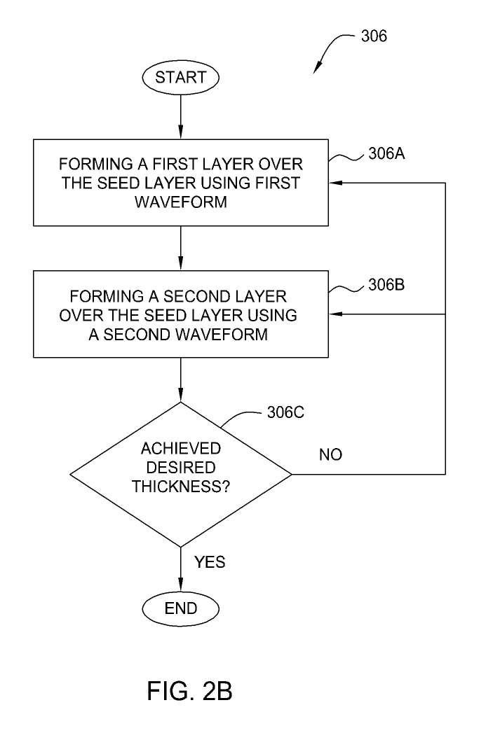

FIG. 2A illustrates a series of method steps 300 that are used to form a solar cell containing conductive metal interconnect layer(s) that have a low intrinsic stress. The processes described below may be used to form a solar cell having interconnects formed using any conventional device interconnection style or technique. Thus while the embodiments described herein are discussed in conjunction with the formation of a device that uses a PUM type interconnect, this configuration is not intended to be limiting as to the scope of the invention.

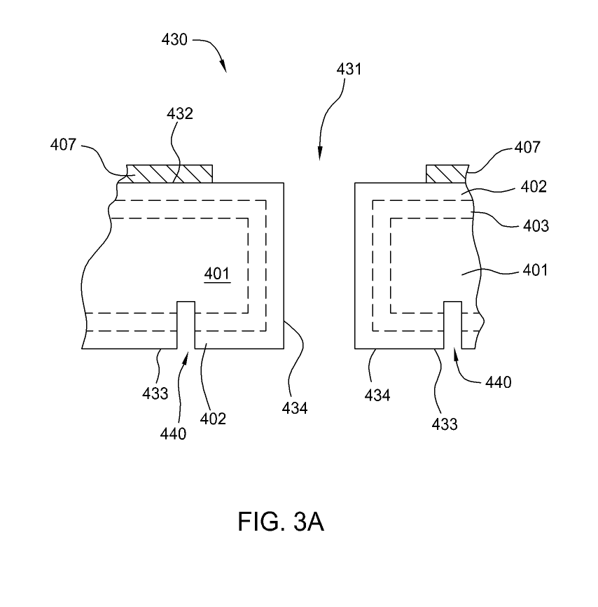

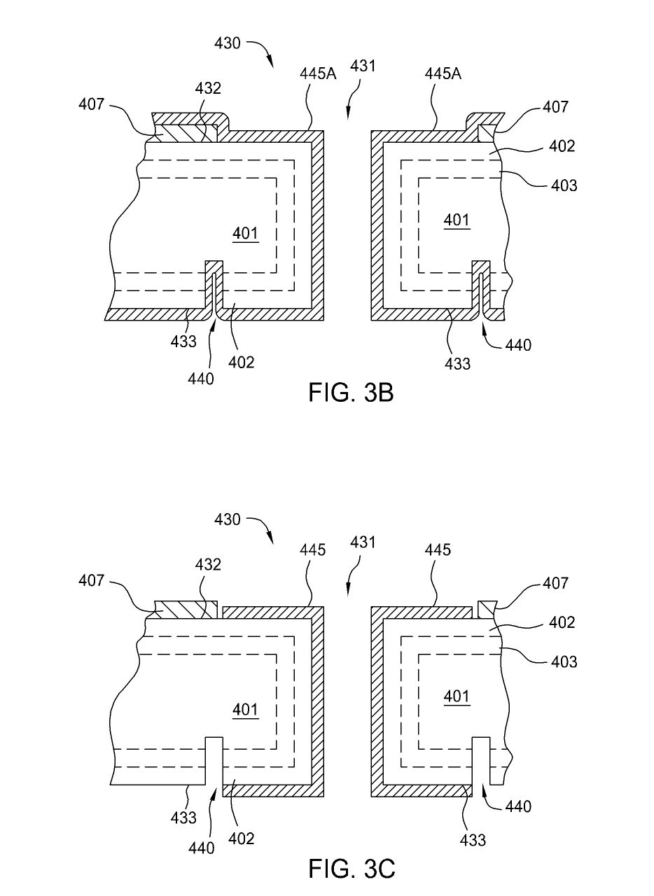

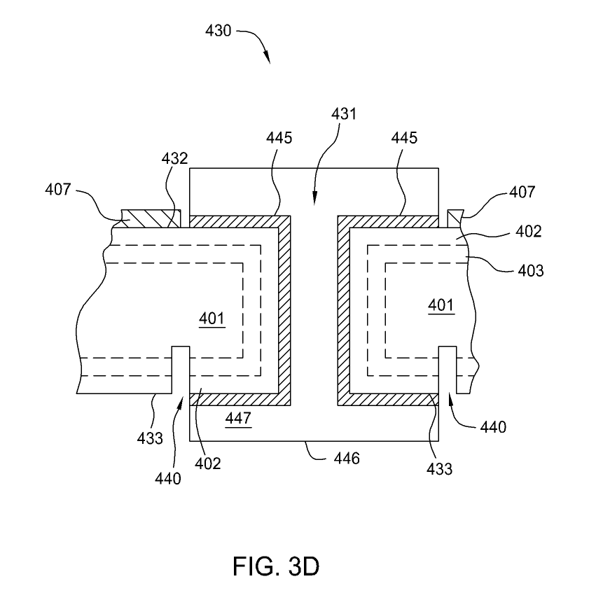

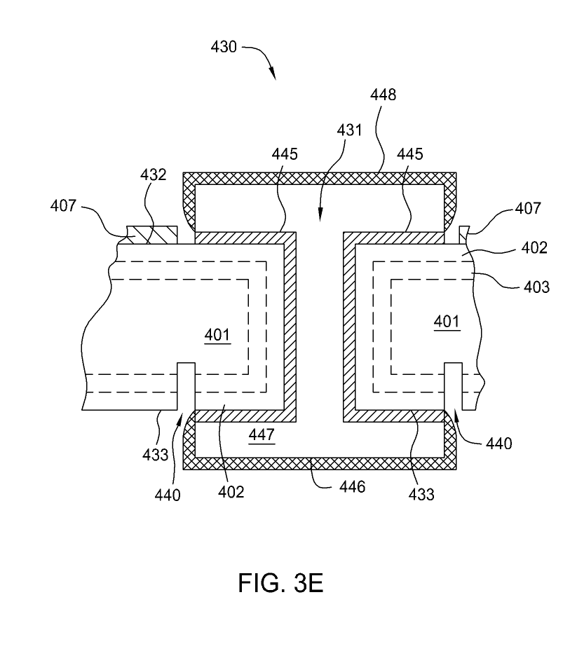

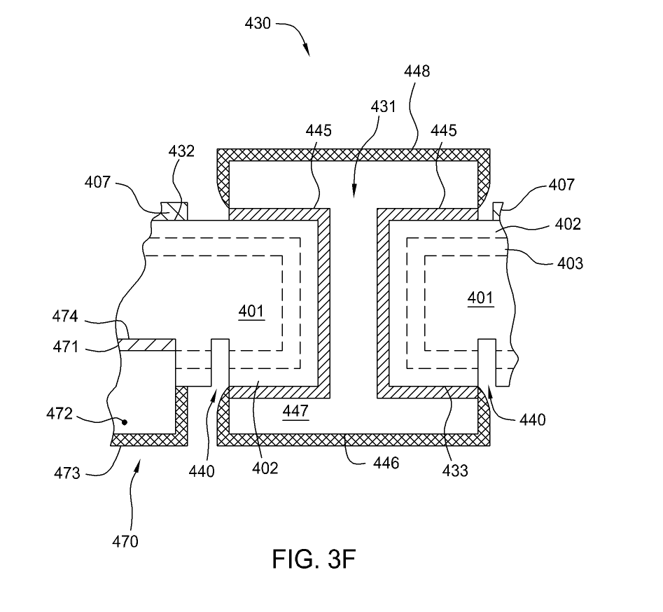

FIGS. 3A-3D illustrate the various states of a metallized substrate 430 after each step of method steps 300 has been performed. The method steps 300 start with step 302 in which a substrate 401 (FIG. 3A) is formed using conventional solar cell and/or semiconductor fabrication techniques. The substrate 401 may be formed from single crystal or polycrystalline silicon materials. Examples of these substrate fabrication process are the EFG process (Edge-defined Film-fed Growth) (e.g., U.S. Pat. No. 5,106,763), the RGS (Ribbon Growth on Substrate) process (e.g., U.S. Pat. No. 4,670,096, U.S. Pat. No. 5,298,109, DE 4,105,910 A1) and the SSP ribbon process (Silicon Sheets from Powder) (e.g., U.S. Pat. No. 5,336,335, U.S. Pat. No. 5,496,446, U.S. Pat. No. 6,111,191, and U.S. Pat. No. 6,207,891). In one example an n-type region 402 is disposed over the substrate 401 that has been doped with a p-type dopant. The n-type region 402 can be formed using conventional chemical vapor deposition (CVD) process, by driving-in an n-type dopant using a diffusion furnace, or other similar doping or film deposition techniques. The formed p-n junction will form a p-n junction region 403. The arc layer 407, or antireflective coating, can be formed using a physical vapor deposition (PVD) or CVD technique. The plurality of features 431 formed between the light-receiving surface 432 and the backside 433 of substrate 401 and across the substrate 401 surface can be formed using a conventional lithography and wet or dry etching semiconductor processing techniques or by use of conventional laser drilling processes. The junction isolation gap 440 may also be formed by use of a laser drilling or similar semiconductor etching techniques.

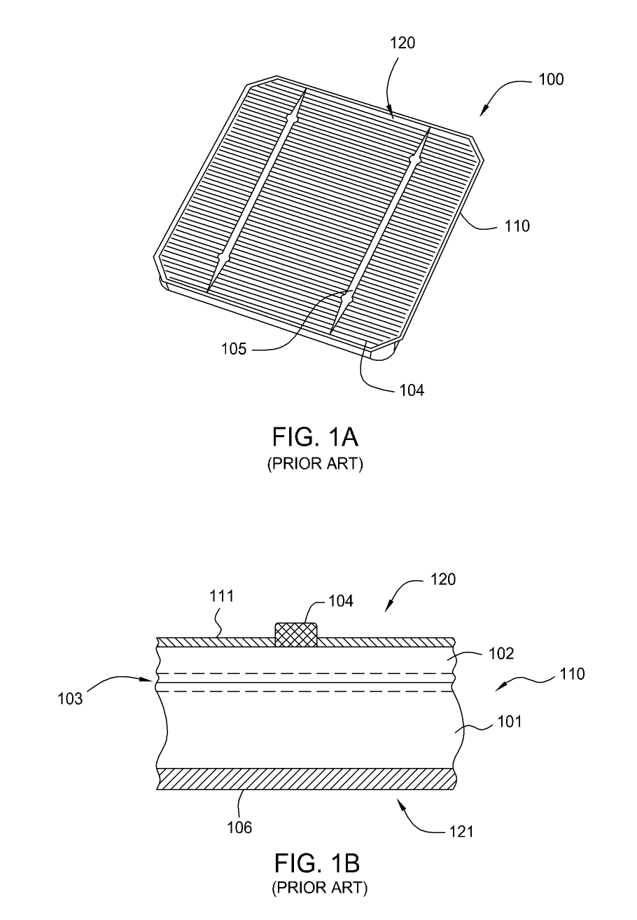

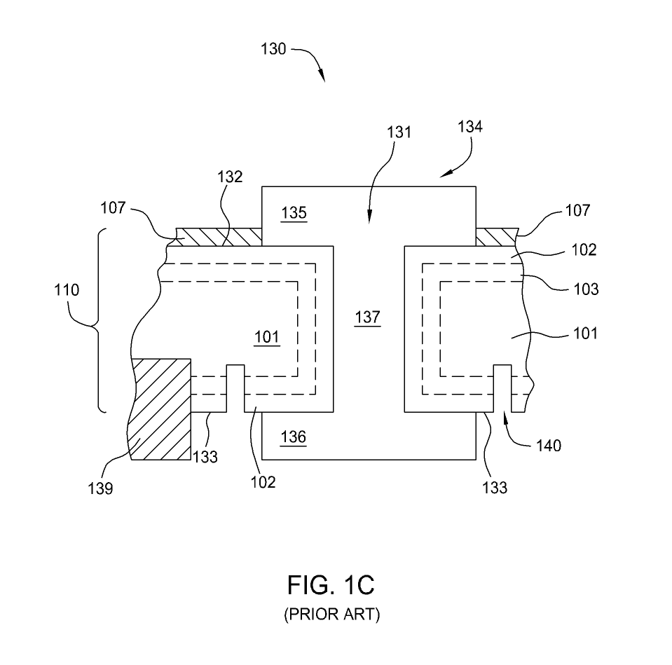

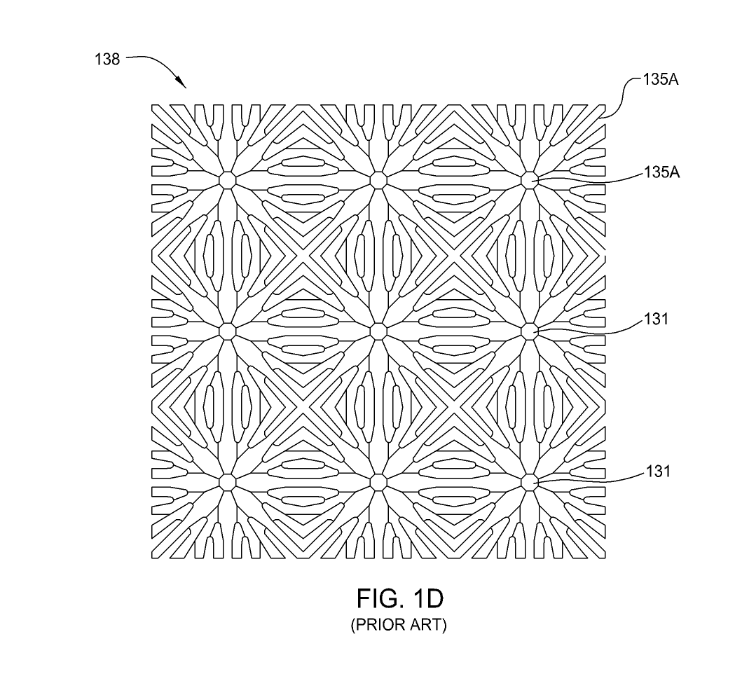

In the next step, step 304, as shown in FIG. 3C, a seed layer 445 is formed on desired regions of the substrate surface using a conventional selective electroless or selective CVD deposition process. In one embodiment, the light-receiving side of the solar cell has a seed layer 445 that is an interconnected metal pattern that is similar to the pattern shown in FIG. 1D, which is discussed above. An example of electroless deposition process that may be used to grow a seed layer 445 on a doped silicon region is further described in the U.S. patent application Ser. No. 11/385,047 [APPM 9916.02], filed Mar. 20, 2006, U.S. patent application Ser. No. 11/385,043 [APPM 9916.04], filed Mar. 20, 2006, and U.S. patent application Ser. No. 11/385,041 [APPM 10659], filed Mar. 20, 2006, which are all incorporated by reference in their entirety. In yet another embodiment, the seed layer is formed by use of an inkjet, rubber stamping, or any technique for the pattern wise deposition (i.e., printing) of a metal containing liquid or colloidal media on the surface of the substrate. After depositing the metal containing liquid or colloidal media on the surface of the substrate it is generally desirable to subsequently perform a thermal post treatment to remove any solvent and promote adhesion of the metal to the substrate surface. An example of pattern wise deposition process that may be used to form a seed layer 445 on a doped silicon region is further described in the U.S. patent application Ser. No. 11/530,003 [APPM 10254], filed Sep. 7, 2006, which is incorporated by reference in its entirety.

In one embodiment, the seed layer 445 is formed over desired regions of the substrate surface by use of a two step seed layer formation process in which a blanket seed layer 445A (FIG. 3B) is formed on the surface of the substrate and then a portions of the blanket seed layer are removed using one or more conventional etching techniques to form a seed layer 445 on desired regions of the substrate surface, as shown in FIG. 3C. In one example, as shown in FIG. 3B, a blanket seed layer 445A is deposited over the complete surface of the substrate using a chemical vapor deposition (CVD), molecular beam epitaxy (MBE), or atomic layer deposition (ALD), or physical vapor deposition (PVD) process. Next, using conventional masking and wet etching techniques portions of the blanket seed layer 445A are preferentially removed from areas of the substrate surface to form a seed layer 445.

In general, the seed layer 445 may contain a conductive material, such as a pure metal, metal alloy or other conductive material. In one embodiment, the seed layer 445 contains one or more metals selected from the group consisting of nickel (Ni), cobalt (Co), titanium (Ti), tantalum (Ta), rhenium (Rh), molybdenum (Mo), tungsten (W), and ruthenium (Ru). It is desirable to select a deposition process and a metal that forms a good electrical contact, or ohmic contact, between the doped silicon region (e.g., n-type region 402) and the deposited metal seed layer 445. In one aspect, the seed layer 445 is selected so that it acts as a barrier to the diffusion of a metal in the subsequently formed contact 446 during subsequent processing steps. For example, the seed layer 445 may contain one or more metals or metal alloys selected from the group consisting of nickel (Ni), cobalt (Co), titanium (Ti), their silicides, titanium tungsten (TiW), titanium nitride (TiN), tantalum (Ta), tantalum nitride (TaN), molybdenum (Mo), tungsten (W), tungsten silicide (WSi), molybdenum silicide (MoSi), and ruthenium (Ru).

In one embodiment, the seed layer 445 consists of at least two layers of metal that are used to promote adhesion to the surface of the substrate, act as a diffusion barrier, and/or promote the growth of a subsequently deposited metal layer 447 contained within the contact 446 (FIG. 3D). In one example, the seed layer 445 contains a first metal layer that is deposited on the substrate surface(s) 434 and a second metal layer that contains copper. In this configuration the second layer is deposited over the first metal layer so that it can act as a seed on which an electrochemically deposited layer can be formed. In this case the first layer may contain one or more metals or metal alloys selected from the group consisting of nickel (Ni), cobalt (Co), titanium (Ti), titanium nitride (TiN), titanium tungsten (TiW), tantalum (Ta), tantalum nitride (TaN), molybdenum (Mo), tungsten (W), and ruthenium (Ru) that is deposited using an electroless deposition process, a conventional physical vapor deposition (PVD) process or a conventional chemical vapor deposition (CVD) process, and a second copper containing layer may be a substantially pure layer or an alloy that contains one or more metals selected from the group consisting of cobalt (Co), tin (Sn), silver (Ag), gold (Au), aluminum (Al), and nickel (Ni). In one embodiment, the second layer may be deposited using an electroless deposition process, a conventional physical vapor deposition (PVD) process or a conventional chemical vapor deposition (CVD) process.

### Metal Fill/Metal Layer Formation Process(es)

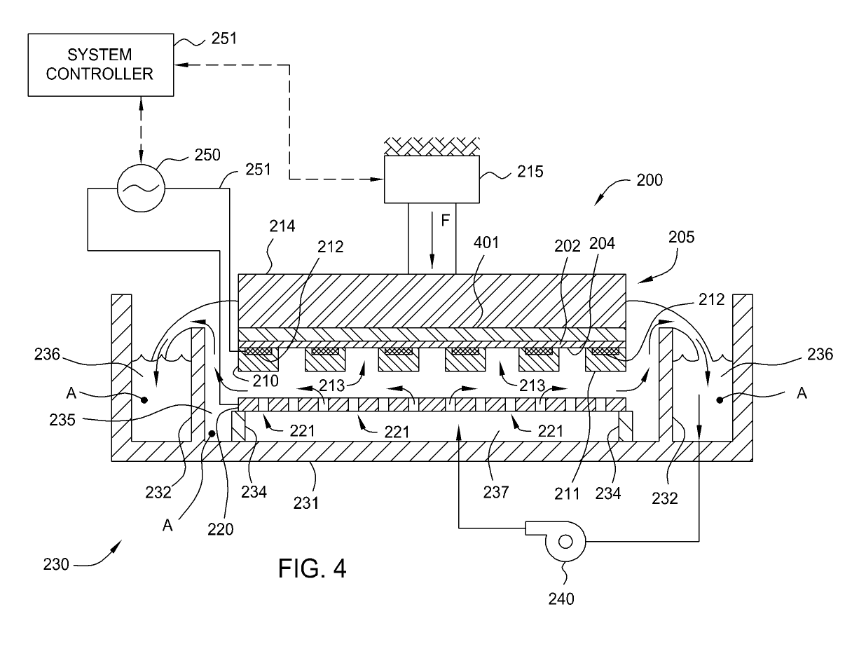

Referring to FIGS. 2A and 3D, in step 306 a contact 446 is formed in the features 431 using an electrochemical deposition process. In this process step, regions of the formed seed layer 445 are cathodically biased relative to an electrode (e.g., electrode 220 in FIG. 4) using a power supply (e.g., electrode 250 in FIG. 4) that causes the ions in an electrolyte, which is in contact with the regions of the seed layer 445 and the electrode, to plate a metal layer 447 on the surface of the seed layer 445 to form the contact 446.

FIG. 4 illustrates one embodiment of an electrochemical plating cell 200 that may be used to electrochemically deposit a metal layer 447 on a seed layer 445 of a metallized substrate 430 during step 306. The electrochemical plating cell 200 generally contains a head assembly 205, an electrode 220, a power supply 250 and a plating cell 230. The head assembly 205 generally contains a thrust plate 214 and a masking plate 210 that is adapted to hold a metallized substrate 430 in a position relative to the electrode 220 during the electrochemical deposition. In one aspect, an mechanical actuator 215 is used to urge the thrust plate 214 and metallized substrate 430 against electrical contacts 212 formed on a surface of the masking plate 210 so that an electrical connection can be formed between a metal layer 202 formed on the surface 203 of the metallized substrate 430 and the power supply 250 through the lead 251. In one case it is desirable to rotate or move the metallized substrate 430 and head assembly 205 relative to the electrode 220 during processing by use of a rotary and/or linear motion actuator (not shown). In another embodiment, the plating system, chamber and plating cell may also utilize a conveyor type design that continuously plate a number of substrates at one time, for example, between 25 and 1000 substrates. Such a system may be horizontally or vertically oriented.

The masking plate 210 is generally made of a dielectric material that has a plurality of features 213 formed therein that allow the electrolyte “A” to contact exposed regions on the substrate surface (e.g., surface 204). This configuration thus allows the preferential formation of an electrochemically deposited metal layer in the exposed regions 204 on the substrate surface when a cathodic bias of a sufficient magnitude is applied to the metal layer 202. In one embodiment, the masking plate 210 is made of glass, a plastic material, or a ceramic material that contains a plurality of features 213 that are formed in the masking plate 210 using conventional machining operations, such as laser cutting, milling, water-jet cutting, drilling, EDM, or stamping processes. The electrical contacts 212 may be a separate and discrete conductive component or a conductive region formed on one or more surfaces of the masking plate 210. The electrical contacts 212 may be formed from a metal, such as platinum, gold, or nickel, or another conductive material, such as graphite, copper Cu, phosphorous doped copper (CuP), and platinum coated titanium (Pt/Ti).

The plating cell 230 generally contains a cell body 231 and an electrode 220. The cell body 231 will generally contain a plating region 235 and an electrolyte collection region 236 that contains an electrolyte (e.g., item “A”) that is used to electrochemically deposit the metal layer on the substrate surface. In operation it is generally desirable to pump an electrolyte “A” from the electrolyte collection region 236 through a plenum 237 formed between the electrode 220 and the support features 234 past the features 213 formed in the masking plate 210 and then over a weir 232 separating the plating region 235 and to the electrolyte collection region 236, by use of a pump 240. In one aspect, the electrode 220 may be supported on one or more support features 234 formed in the cell body 231. In one embodiment, the electrode 220 contains a plurality of holes 221 that allow the electrolyte “A” passing from the plenum 237 to the plating region 235 to be uniformly distributed across masking plate 210 and contact at least one surface on the metallized substrate 430. The fluid motion created by the pump 240 allows the replenishment of the electrolyte components at the exposed region 204 that is exposed at one ends of the features 213. The electrode 220 may be formed from material that is consumable (e.g., copper) during the electroplating reaction, but is more preferably formed from a non-consumable material. A non-consumable electrode may be made of a conductive material that is not etched during the formation the metal layer 202, such as platinum or ruthenium coated titanium.

The system controller 251 is adapted to control the various components used to complete the electrochemical process performed in the electrochemical plating cell 200. The system controller 251 is generally designed to facilitate the control and automation of the overall process chamber and typically includes a central processing unit (CPU) (not shown), memory (not shown), and support circuits (or I/O) (not shown). The CPU may be one of any form of computer processors that are used in industrial settings for controlling various system functions, chamber processes and support hardware (e.g., detectors, robots, motors, gas sources hardware, etc.) and monitor the electrochemical plating cell processes (e.g., electrolyte temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 251 determines which tasks are performable on a substrate. Preferably, the program is software readable by the system controller 251 that includes code to perform tasks relating to monitoring and execution of the electrochemical process recipe tasks and various chamber process recipe steps.

In one embodiment of step 306, one or more direct current (DC) and/or pulse plating waveforms are delivered to the seed layer 445 during the electrochemical deposition process to form the layer 447 that has desirable electrical and mechanical properties. FIG. 2B illustrates a series of method steps that may be performed during the electrochemical plating step, or step 306. In one aspect, during step 306, an electrochemical plating process is performed to deposit a metal layer that has a thickness that is at least sufficient to substantially fill the feature 431 (FIG. 3A). According to embodiments of the invention, the feature 431 is filled with the metal in a void-free and seam-free manner by pulse plating techniques using one or more modulated waveforms. The applied bias may have a waveform that is DC and/or a series of pulses that may have a varying height, shape and duration to substantially fill the feature 431. The concentration gradients of metal ions, additives or suppressors in the proximity of the feature 431 are affected by the sequencing and durations of deposition and dissolution pulses. For example, it is believed that the duration of a deposition pulse controls the deposition on the sidewall of the feature, while the dissolution pulse creates additional metal ions and thus, a concentration gradient of these ions, around the feature. By dissolving some deposited metal from the top of the feature, an electrodissolution pulse (or reverse pulse) allows sufficient time for bottom-up growth within the high aspect ratio feature, without void or seam formation. Furthermore, the deposition and dissolution rates can be controlled by varying the magnitudes of the respective electrical pulses.

Referring to FIGS. 2B and 3C-3D, in step 306A a first waveform is applied to the seed layer 445 by use of a power supply 250 to cause some electrochemical activity at the surface of the seed layer. In one embodiment, as shown in FIG. 2B, a first layer is formed by cathodically biasing the seed layer using a first wave form. In this case, while the bias applied to the seed layer need not always be cathodic, the time average of the energy delivered by the application of the first waveform is cathodic and thus will deposit a metal on the surface of the seed layer 445. In another embodiment, it may be desirable to have a time average that is anodic (i.e., dissolution of material) to clean the surface of the seed layer prior to performing the subsequent filling process steps.

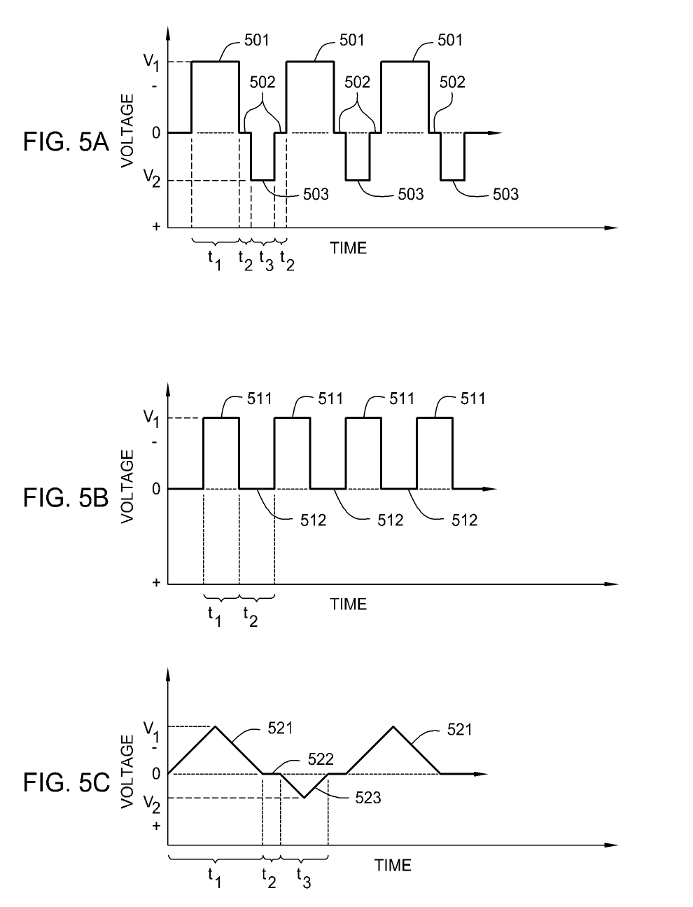

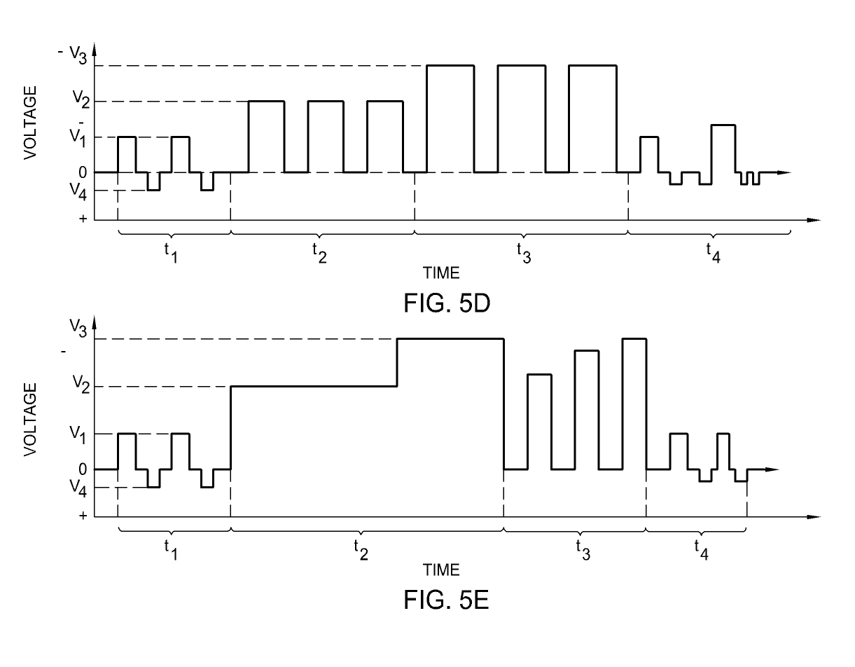

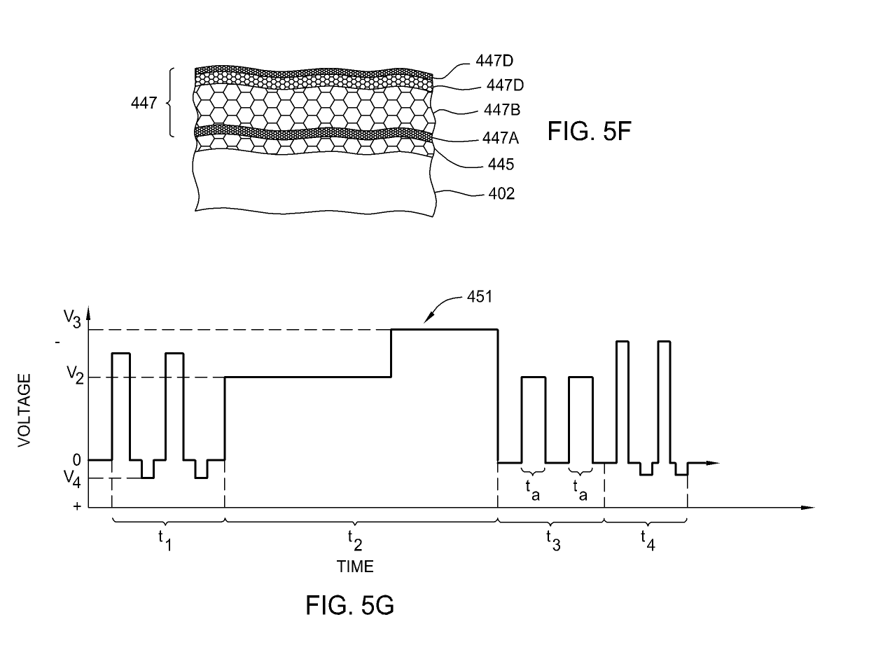

FIGS. 5A-5C illustrate various examples of waveforms that may be used alone or in conjunction with other waveforms to fill the feature 431. It should be noted that while FIGS. 5A-5D illustrate graphs of waveforms as an applied voltage as a function of time, one skilled in the art would appreciate that these waveforms could also be represented as a function of current versus time without varying from the basic scope of the invention. FIG. 5A illustrates a square-wave type waveform that has a cathodic pulse 501 that has a magnitude of V₁ and a duration t₁, an anodic pulse 503 that has a magnitude V₂ and a duration t₃, and a plurality of rest states 502 that have a low applied voltage (e.g., about 0-0.1 volts) for a duration of t₂. The term for a waveform illustrated in FIG. 5A are often described as “pulse reverse” waveform. In this configuration the modulated waveform contains electrical pulses of opposite polarities, along with time intervals of no electrical pulses, or “off-times”. The off-times in the plating waveforms can be used to allow re-distribution of various chemical species in the plating solution around the features 431 to achieve a desirable deposition profile. It should be noted that in some cases where the diffusion boundary layer is small and/or the metal ion concentration is relatively high there may be no need to have the one or more rest states 502 in the waveform, and thus the cathodic pulse 501 may transition directly into the anodic pulse 503, and vice versa, without varying from the basic scope of the invention.

FIG. 5B illustrates a square-wave type waveform that has a cathodic pulse 511 that has a magnitude of V₁ and a duration t₁ and a plurality of rest states 512 that are delivered at a low applied voltage (e.g., about 0-0.1 volts) for a duration of t₂. The term for a waveform illustrated in FIG. 5B are often described as “forward pulse” waveform. FIG. 5C illustrates a triangular shaped waveform that has a cathodic pulse 521 that peaks at a magnitude of V₁ and lasts for a duration t₁, an anodic pulse 523 that peaks at a magnitude V₂ and lasts for a duration t₃, and a plurality of rest states 522 that have a low applied voltage for a duration of t₂. While the waveform shapes illustrated herein are square or triangular shape this is not intended to be limiting as to the possible waveform shapes that may be used to form the feature 431. In some case waveforms that are, for example sinusoidal, exponential, second degree polynomial, or third degree polynomial in shape may be used.

Referring to FIG. 2B, an optional step 306B is performed in which a second waveform is applied to the seed layer 445 by use of a power supply 250 to cause some electrochemical activity at the surface of the seed layer 445 or the first layer deposited in step 306A. In one embodiment, as shown in FIG. 2B, a second layer is formed by cathodically biasing the seed layer and first layer using a second wave form. The second waveform may have a shape similar to the shapes illustrated in FIGS. 5A-5C or be a DC type bias.

In step 306C the system controller 251 or user input is used to decide if a desired thickness has been achieved during the electrochemical plating method steps 300 and if not steps 306A and/or 306B may be repeated a number of times until a desired thickness has been reached. In one example, as shown in FIG. 5D, a series of different waveforms are applied to the seed layer 445 to fill the feature 431. As shown a first waveform having both cathodic and anodic pulses of a desired magnitude (e.g., V₁ and V₄, respectively) and duration are delivered to the seed layer 445 for a period of time t₁. Next, a second waveform containing only cathodic pulses of a magnitude V₂ are delivered for a period of time t₂ and then a third waveform containing only cathodic pulses of a magnitude V₃ are delivered for a period of time t₃. Finally, a fourth waveform having both cathodic and anodic pulses of a desired magnitude (e.g., V₁ and V₄, respectively) and duration are delivered to the seed layer 445 for a period of time t₄.

In another example, as shown in FIG. 5E, a series of different waveforms are applied to the seed layer 445 to fill the feature 431. As shown in FIG. 5E, a first waveform having both cathodic and anodic pulses of a desired magnitude (e.g., V₁ and V₄, respectively) and duration are delivered to the seed layer 445 for a period of time t₁. Next, a second DC type waveform having a magnitude V₂ and V₃ are delivered during a period of time t₂ and then a third pulse type waveform having an increasing magnitude (e.g., between V₂ and V₃,) is delivered to the seed layer 445 during the period of time t₃. Finally, a fourth waveform having both cathodic and anodic pulses of a desired magnitude (e.g., V₁ and V₄, respectively) and duration are delivered to the seed layer 445 during a period of time t₄. It should be noted that the shape of the pulses, the relative magnitudes of the pulses within each waveform, the number pulse per waveform, and/or the duration of each pulse or waveform illustrated in this example are not intended to be limiting as to the scope of the invention described herein.

It is believed that by controlling the magnitude, duration and polarity of successive pulses the grain size of the metal layer formed using an electrochemical deposition process can be controlled. It is generally well known that by using pulse plating waveform that has many rapid pulses that have a high magnitude or a number of pulses having alternating polarity will generate a layer that has a lower stress and generally a smaller grain size than an electrochemically deposited layer that is formed using a DC waveform or pulse type waveform that are of a longer duration and/or have a smaller pulse magnitude. Therefore, by controlling the waveform, deposition rate, and chemistry used to form the metal layer 447 having a varying grain size a low stress metal layer can be formed that is able to fill the features 431 formed on the substrate surface.

FIG. 5F illustrates an example of a cross-sectional view of the seed layer 445 and the metal layer 447 that illustrates an example of multiple different grain sizes that may formed during the metallization process. As shown the grain size of the various regions 447A-447D in the metal layer 447 can be formed by the application of the electrochemical deposition waveform shown in FIG. 5G. In this example, the first region 447A contains small grains due to the application of the relatively large magnitude, short duration and alternating polarity of the waveform used during the first period t₁ of the waveform 451. The grain size of the second region 447B contains large sized grains due to the application of a cathodic DC type waveform that are formed during period t₂. The grain size of the third region 447C, which is formed during period t₂ contains moderately sized grains due to the application of a waveform that delivers pulses that have a longer duration tₐ and are only cathodic in nature. Finally the fourth region 447D contains small grains due to the application of the relatively large magnitude, short duration and alternating polarity of the waveform used during the fourth period t₄. It is believed that by controlling the grain size of the metal contained in the formed layer the stress in the formed layer can be modulated and controlled. It is also believed that by adjusting the grain size through the adjustment of the elements in the applied waveform the stress in the overall layer can be controlled.

### Electrolyte Solution

In general, it is desirable to form a feature 431 with a metal layer that doesn't have defects (e.g., seams, voids or gaps) and fills in a bottom-up manner (e.g., from the middle of the through-Si hole). To enhance the growth of a defect free low stress film that fills from the bottom-up (middle of through Si hole) the electrochemical process performed in the electrochemical plating cell 200 utilizes an electrolyte solution containing a metal ion source and an acid solution. In some cases one or more additives, such as an accelerator, a suppressor, a leveler, a surfactant, a brightener, or combinations thereof may be added to the electrolyte solution to help control the grain size and uniformity of the electrochemically deposited metal layer(s). However, additives generally make the control of the electrochemical process more complex and make the cost of the consumables generated during the electrochemical plating process to increase, since they are generally consumed or breakdown during the electrochemical process. In one embodiment, to increase the planarization power, the electrolyte can optionally contain an inorganic acid, (e.g., sulfuric acid, phosphoric acid or pyrophosphoric acid), various inorganic supporting salts, and other additives that may be used to improve the quality of plated surfaces (e.g., oxidizers, surfactants, brighteners, etc.).

In one example, the metal ion source within the electrolyte solution used in step 306 in FIGS. 2A and 2B is a copper ion source. In one embodiment, the concentration of copper ions in the electrolyte may range from about 0.1 M to about 1.1M, preferably from about 0.4 M to about 0.9 M. Useful copper sources include copper sulfate (CuSO₄), copper chloride (CuCl₂), copper acetate (Cu(CO₂CH₃)₂), copper pyrophosphate (Cu₂P₂O₇), copper fluoroborate (Cu(BF₄)₂), derivatives thereof, hydrates thereof or combinations thereof. The electrolyte composition can also be based on the alkaline copper plating baths (e.g., cyanide, glycerin, ammonia, etc) as well.

In one example, the electrolyte is an aqueous solution that contains between about 200 and 250 g/l of copper sulfate pentahydrate (CuSO₄.5(H₂O)), between about 40 and about 70 g/l of sulfuric acid (H₂SO₄), and about 0.04 g/l of hydrochloric acid (HCl). In some cases it is desirable to add a low cost pH adjusting agent, such as potassium hydroxide (KOH) or sodium hydroxide (NaOH) to form an inexpensive electrolyte that has a desirable pH to reduce the cost of ownership required to form a metal contact structure for a solar cell. In some cases it is desirable to use tetramethylammonium hydroxide (TMAH) to adjust the pH.

In another example, the electrolyte is an aqueous solution that contains between about 220 and 250 g/l of copper fluoroborate (Cu(BF₄)₂), between about 2 and about 15 g/l of tetrafluoroboric acid (HBF₄), and about 15 and about 16 g/l of boric acid (H₃BO₃). In some cases it is desirable to add a pH adjusting agent, such as potassium hydroxide (KOH), or sodium hydroxide (NaOH) to form an inexpensive electrolyte that has a desirable pH to reduce the cost of ownership required to form a metal contact structure for a solar cell. In some cases it is desirable to use tetramethylammonium hydroxide (TMAH) to adjust the pH.

In yet another example, the electrolyte is an aqueous solution that contains between about 60 and about 90 g/l of copper sulfate pentahydrate (CuSO₄.5(H₂O)), between about 300 and about 330 g/l of potassium pyrophosphate (K₄P₂O₇), and about 10 to about 35 g/l of 5-sulfosalicylic acid dehydrate sodium salt (C₇H₅O₆SNa.2H₂O). In some cases it is desirable to add a pH adjusting agent, such as potassium hydroxide (KOH), or sodium hydroxide (NaOH) to form an inexpensive electrolyte that has a desirable pH to reduce the cost of ownership required to form a metal contact structure for a solar cell. In some cases it is desirable to use tetramethylammonium hydroxide (TMAH) to adjust the pH.

In yet another example, the electrolyte is an aqueous solution that contains between about 30 and about 50 g/l of copper sulfate pentahydrate (CuSO₄.5(H₂O)), and between about 120 and about 180 g/l of sodium pyrophosphate decahydrate (Na₄P₂O₇.10(H₂O)). In some cases it is desirable to add a pH adjusting agent, such as potassium hydroxide (KOH), or sodium hydroxide (NaOH) to form an inexpensive electrolyte that has a desirable pH to reduce the cost of ownership required to form a metal contact structure for a solar cell. In some cases it is desirable to use tetramethylammonium hydroxide (TMAH) to adjust the pH.

In one embodiment, it may be desirable to add a second metal ion to the primary metal ion containing electrolyte bath (e.g., copper ion containing bath) that will plate out or be incorporated in the growing electrochemically deposited layer or on the grain boundaries of the electrochemically deposited layer. The formation of a metal layer that contains a percentage of a second element can be useful to reduce the intrinsic stress of the formed layer and/or improve its electrical and electromigration properties. In one example, it is desirable to add an amount of a silver (Ag), nickel (Ni), zinc (Zn), or tin (Sn) metal ion source to a copper plating bath to form a copper alloy that has between about 1% and about 4% of the second metal in the deposited layer.

In one example, the metal ion source within the electrolyte solution used in step 306 in FIGS. 2A and 2B is a silver, tin, zinc or nickel ion source. In one embodiment, the concentration of silver, tin, zinc or nickel ions in the electrolyte may range from about 0.1 M to about 0.4M. Useful nickel sources include nickel sulfate, nickel chloride, nickel acetate, nickel phosphate, derivatives thereof, hydrates thereof or combinations thereof.

### Contact Interface Layer

Referring to FIGS. 2A and 3E, in step 308 an optional contact interface layer 448 is deposited over the surface of the metal layer 447 formed during step 306. The contact interface layer 448 can be formed using an electrochemical deposition process, an electroless deposition process, a CVD deposition process, or other comparable deposition processes to form a good ohmic contact between the formed features 431 and an external interconnection bus (not shown) that is adapted to connect one or more solar cells together. In one embodiment, the contact interface layer 448 is formed from a metal that is different from the metal contained in the metal layer 447. In this configuration the contact interface layer 448 may be formed from a pure metal or metal alloy that contains metals, such as tin (Sn), silver (Ag), gold (Au), lead (Pb), copper (Cu), or ruthenium (Ru).

In one embodiment, the contact interface layer 448 is formed by use of an electrochemical process. In some cases it is desirable to perform step 308 in the same electrochemical plating cell as step 306 was performed. In this configuration, the seed layer 445 and metal layer 447 are cathodically biased relative to an electrode (e.g., electrode 220 in FIG. 4) using a power supply that causes the ions in an contact interface layer electrolyte, which is brought into contact with the seed layer 445, metal layer 447 and the electrode, to plate the contact interface layer 448 on the surface of the seed layer 445 and/or metal layer 447. In the case where the contact interface layer 448 is formed in the same electrochemical plating cell 200 as the metal layer 447 and the contact interface layer 448 contains one or more different elements than the metal layer 447 the electrolyte used to form the metal layer will need to be discarded and replaced with the new contact interface layer electrolyte to form the contact interface layer 448.

### Contact Interface Layer Electrolyte Solution

In one embodiment, the contact interface layer 448 contains tin (Sn) and is deposited by use of an electrochemical deposition process. The concentration of tin ions in the contact interface layer electrolyte may range from about 0.1 M to about 1.1 M. Useful tin sources include tin sulfate (SnSO₄), tin chloride (SnCl₂), and tin fluoroborate (Sn(BF₄)₂), derivatives thereof, hydrates thereof or combinations thereof. In another embodiment, to increase the planarization power, the electrolyte can optionally contain an inorganic acid, (e.g., sulfuric acid, phosphoric acid or pyrophosphoric acid), various inorganic supporting salts, and other additives that may be used to improve the quality of plated surfaces (e.g., oxidizers, surfactants, brighteners, etc.). The electrolyte composition can also be based on the alkaline tin plating baths (e.g., cyanide, glycerin, ammonia, etc) as well. The electrolyte may also contain methane-sulfonic acid (MSA).

In one example, the electrolyte is an aqueous solution that contains between about 200 and 250 g/l of tin sulfate pentahydrate (SnSO₄.5(H₂O)), between about 40 and 70 g/l of sulfuric acid (H₂SO₄), and about 0.04 g/l of hydrochloric acid (HCl). In some cases it is desirable to add one or more organic additives (e.g., levelers, accelerators, suppressors) to promote uniform growth of the deposited layer. In some cases it is desirable to add a low cost pH adjusting agent, such as potassium hydroxide (KOH) or sodium hydroxide (NaOH) to form an inexpensive electrolyte that has a desirable pH to reduce the cost of ownership required to form a metal contact structure for a solar cell. In some cases it is desirable to use tetramethylammonium hydroxide (TMAH) to adjust the pH.

In an effort to reduce the production time to form the metal layers 447 and/or 448 it is desirable to take steps to maximize the plating rate, while producing a low stress uniform layer that has good electrical properties. Typical methods that can be used to improve the plating rate include agitation of the electrolyte solution, increase the electrolyte flow and or motion of the substrate in the electrolyte. In one aspect, the plating rate is increased by controlling the temperature of electrolyte. In one embodiment, the temperature of the electrolyte is controlled within a range of about 18° C. and about 85° C., and preferably between about 30° C. and about 70° C. to maximize the plating rate. It has been found that the higher the temperature the faster the plating rate.

### Multiple Metallization Steps

The embodiments discussed above in conjunction with FIGS. 2-5 can be used to form one or more of the contacts 446 on a surface of the substrate. While it is generally desirable to form all of the various contact structures used to form a solar cell device at one time, this is sometimes not possible due to various processing constraints. In some cases two metallization processes are required, for example, to form a front side contact, as shown in FIGS. 3A-3E, and a second metallization process to form a second contact on a different region of the substrate 430, such as a backside contact shown in FIG. 3F.

As shown in FIG. 3F, the second metallization step can be used to form the backside contact 470 that is adapted to connect to an active region (e.g., p-type region in FIG. 3A) of the solar cell device. In this example, a recess 474 is first formed in the substrate 401 so that the subsequent metal layers can make direct contact to the base region of the substrate 401. Generally, the recess 474 may be formed using conventional lithography, wet etching, dry etching and/or laser ablation type processes. Next, a seed layer 471 can be formed using the process steps described above in conjunction with step 304 or other similar techniques. Finally, a metal layer 472 and an interconnect layer 473 may be formed using the process steps described above in conjunction with steps 306-308 and FIGS. 2B, 3D-3E, 4, and 5A-5G. While the processes described above may be used to form a solar cell uses a PUM type interconnection scheme this configuration is not intended to be limiting as to the scope of the invention.

### Post Processing Steps

Referring to FIG. 2A, in step 310 one or more post processing steps are performed to reduce the stress or improve the properties of the deposited metal layers (e.g., metal layers 445, 446, 448, 471, 472, 473). The post processing steps that may be performed during step 310 may be include an anneal step, a clean step, a metrology step or other similar types of processing steps that are commonly performed on after metallizing a surface of the substrate. In one embodiment, an annealing step is performed on the solar cell substrate to reduce or even out the intrinsic stress contained in the formed metal layers. In one aspect, the annealing process is performed at a temperature between about 200 and 450° C. in a low partial pressure of nitrogen environment. In one aspect, an anneal process is used to enhance the electrical contact between the formed metal layers and/or the adhesion of the metal layers to the substrate surface, and silicide formation.

While the foregoing is directed to embodiments of the present invention, other and further embodiments of the invention may be devised without departing from the basic scope thereof, and the scope thereof is determined by the claims that follow.

What is claimed is:

1. A method for forming a metal interconnect in a solar cell substrate, comprising:
providing a substrate that has either an n-type region or a p-type region generally adjacent to a surface of a substrate;
forming a seed layer that is in electrical communication with the n-type region or the p-type region on the surface of the substrate; and
forming a first metal layer over the seed layer by immersing the seed layer and an electrode in a first electrolyte and biasing the seed layer relative to the electrode using one or more waveforms delivered from a power supply.

2. The method of claim 1, wherein the surface is a light-receiving surface or a backside surface.

3. The method of claim 1, wherein the one or more waveforms comprises a first waveform that is adapted to form a first metal layer that has a first grain size and a second waveform that is adapted to form a second metal layer that has a second grain size.

4. The method of claim 1, wherein the first electrolyte contains a copper salt selected from a group consisting of copper sulfate, copper chloride, copper acetate, copper pyrophosphate, and copper fluoroborate.

5. The method of claim 1, wherein first metal layer comprises copper and at least one element selected from a group consisting of silver, nickel, zinc and tin.

6. The method of claim 1, further comprising forming a second metal layer over the first metal layer by immersing the first metal layer and an electrode in a second electrolyte and biasing the first metal layer relative to the electrode using one or more waveforms delivered from a power supply.

7. The method of claim 6, wherein the second electrolyte contains a metal ion selected from a group consisting of tin, silver, copper, gold, lead and ruthenium.

8. The method of claim 1, wherein the waveform comprises a DC component that lasts a first period of time and pulse plating component that lasts for a second period of time, wherein the pulse plating component is a forward pulse or a pulse reverse type pulse.

9. A method for forming a metal interconnect on a solar cell substrate, comprising:
providing an electrolyte container configured to receive and maintain a first electrolyte therein, the electrolyte container having an electrode disposed within the electrolyte container;
providing a head assembly positioned above the electrolyte container, the head assembly including a substrate holder for supporting a substrate and a first electrode, wherein the substrate holder covers the processing surface of the substrate and the substrate holder has a plurality of features formed therein that preferentially allow regions of the processing surface to contact the first electrolyte;
positioning a substrate in contact with the first electrolyte, the substrate holder and the first electrode; and
applying one or more waveforms to the first electrode and a second electrode in an electroplating process.

10. The method of claim 9, wherein the substrate has either an n-type region or a p-type region generally adjacent to a light-receiving surface of a substrate and a seed layer that contacts the n-type region or the p-type region on the light-receiving surface of the substrate.

11. The method of claim 9, wherein the one or more waveforms comprises a first waveform that is adapted to form a first metal layer that has a first grain size and a second waveform that is adapted to form a second metal layer that has a second grain size.

12. The method of claim 9, wherein the first electrolyte contains a copper salt selected from a group consisting of copper sulfate, copper chloride, copper acetate, copper pyrophosphate, and copper fluoroborate.

13. The method of claim 12, wherein first electrolyte comprises copper ion and at least one metal ion selected from a group consisting of silver, nickel, zinc and tin.

14. The method of claim 9, further comprising:
removing the first electrolyte from the electrolyte container;
delivering a second electrolyte to the electrolyte container, wherein the second electrolyte contains a metal ion that is not found in the first electrolyte; and
applying one or more waveforms to the first electrode and the second electrode, wherein the processing surface and the second electrode are in contact with the second electrolyte.

15. The method of claim 14, wherein the second electrolyte contains a metal ion selected from a group consisting of tin, silver, gold, lead and ruthenium.

16. The method of claim 9, wherein the one or more waveforms are a pulse reverse, a forward pulse or a DC waveform.

17. The method of claim 9, wherein the waveform comprises a DC component that lasts a first period of time and pulse plating component that lasts for a second period of time, wherein the pulse plating component is a forward pulse or a pulse reverse type pulse.

18. A metal contact structure for a solar cell comprising:
an n-type region disposed on a substrate;
a p-type region disposed on the substrate and adjacent to the n-type region;
a first metal seed layer that is in electrical communication with the n-type region, wherein the first metal seed layer is deposited using a process selected from a group consisting of an electroless deposition process, a physical vapor deposition process, a chemical vapor deposition process and an atomic layer deposition process;
a first metal layer that is formed over the first metal seed layer using an electrochemical deposition process using a first waveform;
a second metal seed layer that is in electrical communication with the p-type region, wherein the second metal seed layer is deposited using a process selected from a group consisting of an electroless deposition process, a physical vapor deposition process, a chemical vapor deposition process and an atomic layer deposition process; and
a second metal layer that is formed over the second metal seed layer using an electrochemical deposition process using a second waveform.

19. The metal contact structure of claim 18, wherein the first metal seed layer and the second metal seed layer each contain at least one metal selected from a group consisting of nickel (Ni), cobalt (Co), titanium (Ti), titanium nitride (TiN), titanium tungsten (TiW), tantalum (Ta), tantalum nitride (TaN), molybdenum (Mo), tungsten (W), aluminum (Al) and ruthenium (Ru).

20. The metal contact structure of claim 18, wherein the first metal seed layer and the second metal seed layer each comprise:
a first layer that contains at least one metal selected from a group consisting of cobalt, titanium, titanium nitride, tantalum, tantalum nitride, molybdenum, tungsten, and ruthenium; and
a second layer that contains at least one metal selected from a group consisting of copper, silver, ruthenium and nickel.

21. The metal contact structure of claim 18, wherein the first metal layer and the second metal layer each contain at least one metal selected from a group consisting of copper, silver, gold, tin, cobalt, rhenium, ruthenium, iron, nickel, zinc, lead, palladium, and/or aluminum.

22. The metal contact structure of claim 18, further comprises:
a third metal layer that is formed over the first metal layer using an electrochemical deposition process; and
a fourth metal layer that is formed over the second metal layer using an electrochemical deposition process.

23. The metal contact structure of claim 22, wherein the third metal layer and the fourth metal layer each contain at least one metal selected from a group consisting of tin, silver, copper, gold, lead and ruthenium.
